(19) United States
(12) Patent Application Publication
(10) Pub. No.: US 2015/0262671 A1
(43) Pub. Date: Sep. 17, 2015

(54) NON-VOLATILE MEMORY DEVICE

(71) Applicant: Kabushiki Kaisha Toshiba, Minato-ku (JP)

(72) Inventors: Kikuko SUGIMAE, Kuwana (JP); Kiyohito NISHIHARA, Yokkaichi (JP); Yoshihisa IWATA, Yokohama (JP); Masumi SAITOH, Yokkaichi (JP); Masayuki ICHIGE, Yokkaichi (JP)

(73) Assignee: Kabushiki Kaisha Toshiba, Minato-ku (JP)

(21) Appl. No.: 14/471,492

(22) Filed: Aug. 28, 2014

Related U.S. Application Data
(60) Provisional application No. 61/952,315, filed on Mar. 13, 2014.

(51) Int. Cl. G11C 16/04; G06F 13/40; G11C 16/12

(52) U.S. Cl. CPC G11C 16/0483; G11C 16/12; G06F 13/4022

(57) ABSTRACT

A nonvolatile memory device according to an embodiment includes: a semiconductor substrate; a memory cell array unit provided on an upper side of the semiconductor substrate; an integrated circuit unit provided between the memory cell array unit and the semiconductor substrate; and a peripheral circuit unit provided on the semiconductor substrate. The integrated circuit unit includes: a first contact electrode electrically connected to one of plurality of first interconnection layers; a second contact electrode connected to the peripheral circuit unit; and a first switching element connected between the first contact electrode and the second contact electrode, and conduction between the first contact electrode and the second contact electrode being controlled by a control circuit unit provided in the peripheral circuit unit.

### CROSS-REFERENCE TO RELATED APPLICATIONS

This application is based upon and claims the benefit of priority from U.S. Provisional Patent Application 61/952,315, filed on Mar. 13, 2014; the entire contents of which are incorporated herein by reference.

### FIELD

Embodiments described herein relate generally to a non-volatile memory device.

### BACKGROUND

In a nonvolatile memory device in which a memory element is disposed in a position where each of a plurality of bit lines and each of a plurality of word lines cross each other, a select transistor is used in order to select a specific bit line (or a specific word line). Such a select transistor is provided between a memory cell array and a buffer resistor, and is usually disposed near the memory cell array.

However, as the number of memory cell arrays stacked increases, also the number of select transistors connected to bit lines (or word lines) increases. Thus, if these select transistors are arranged on a substrate, the area of the nonvolatile memory device increases with the increase of the number of memory cell arrays stacked.

### BRIEF DESCRIPTION OF THE DRAWINGS

FIG. 1 is a block configuration diagram showing a nonvolatile memory device according to an embodiment;

FIG. 2 is a schematic perspective view showing part of a memory cell array unit according to the embodiment;

FIG. 3A is a schematic perspective view showing the memory cell array unit and a circuit structure under the memory cell array unit according to the embodiment, and FIG. 3B is a schematic side view showing the memory cell array unit, and a circuit unit and a semiconductor substrate under the memory cell array unit according to the embodiment;

FIG. 4A is a schematic cross-sectional view showing an integrated circuit unit according to the embodiment, and FIG. 4B is a diagram showing an equivalent circuit of a transistor included in the integrated circuit unit according to the embodiment;

FIG. 5 is a schematic side view showing a memory cell array unit, and a circuit unit and a semiconductor substrate under the memory cell array unit according to a reference example;

FIG. 6 is a schematic side view showing a memory cell array unit, and a circuit unit and a semiconductor substrate under the memory cell array unit according to a modification example of the embodiment;

FIG. 7 is a schematic side view showing a memory cell array unit, and a circuit unit and a semiconductor substrate under the memory cell array unit according to another modification example of the embodiment; and

FIG. 8 is an equivalent circuit diagram of select transistors according to the modification example of the embodiment.

### DETAILED DESCRIPTION

According to one embodiment, a nonvolatile memory device includes: a semiconductor substrate; a memory cell array unit provided on an upper side of the semiconductor substrate; an integrated circuit unit provided between the memory cell array unit and the semiconductor substrate; and a peripheral circuit unit provided on the semiconductor substrate.

The memory cell array unit includes: a plurality of first interconnection layers extending in a first direction; a plurality of second interconnection layers extending in a second direction crossing the first direction; and a memory cell provided in a position, and each of the plurality of first interconnection layers and each of the plurality of second interconnection layers cross each other in the position.

The integrated circuit unit includes: a first contact electrode electrically connected to one of the plurality of first interconnection layers; a second contact electrode connected to the peripheral circuit unit; and a first switching element connected between the first contact electrode and the second contact electrode, and conduction between the first contact electrode and the second contact electrode being controlled by a control circuit unit provided in the peripheral circuit unit.

Hereinbelow, embodiments are described with reference to the drawings. In the following description, identical components are marked with the same reference numerals, and a description of components once described is omitted as appropriate.

### FIRST EMBODIMENT

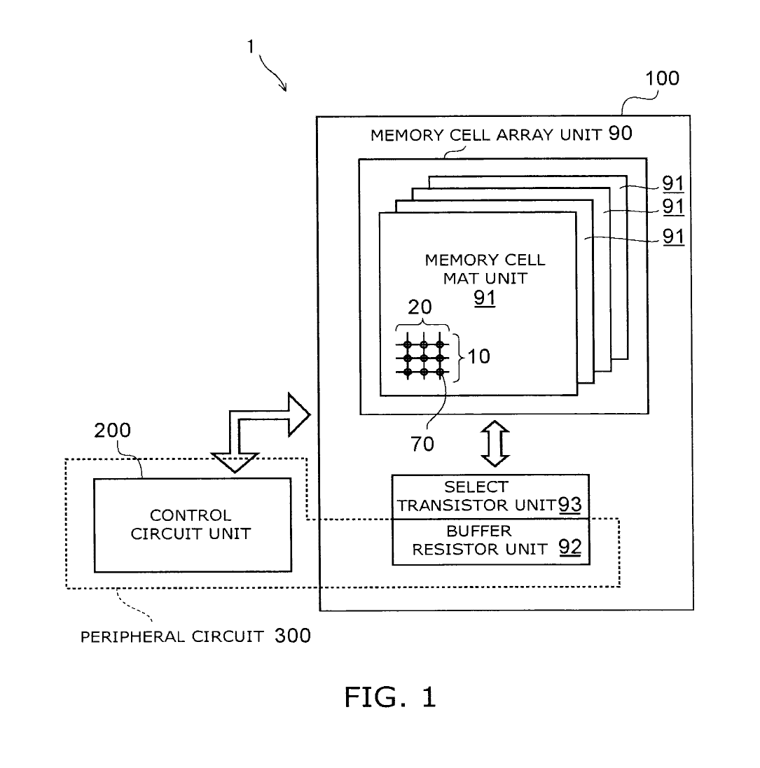

FIG. 1 is a block configuration diagram showing a nonvolatile memory device according to the embodiment.

A nonvolatile memory device 1 includes a memory device unit 100 and a control circuit unit 200 that controls the memory device unit 100.

The memory device unit 100 includes a memory cell array unit 90 and a buffer resistor unit 92 for data transfer between the control circuit unit 200 and the memory cell array unit 90. An integrated circuit unit (select transistor unit) 93 in which select transistors are integrated is provided between the buffer resistor unit 92 and the memory cell array unit 90. The integrated circuit unit (select transistor unit) 93 is also called a hookup circuit unit, and the select transistor is also called a hookup transistor.

The memory cell array unit 90 is divided into a plurality of parts by memory cell mat units 91 in which memory cells are arranged in a matrix configuration. In each memory cell mat unit 91, a plurality of bit lines 10 and a plurality of word lines 20 are arranged so as to cross each other. A memory cell 70 is provided in a position where the bit line 10 and the word line 20 cross each other. A unit including the control circuit unit 200 and the buffer resistor unit 92 is referred to as a peripheral circuit unit 300. The select transistor can make simultaneous selection between an upper and a lower memory cell mat unit 91 and selection of a plurality of bit lines 10. In selecting a plurality of bit lines 10, the switching between an upper and a lower memory cell mat unit 91 is performed using complementary field effect transistors (CMOSFETs) described later.

The control circuit unit 200 controls the electric potential of the bit line 10 and the electric potential of the word line 20 in the memory cell mat unit 91, and performs the data writing, the data reading, and the data erasing of the memory cell 70. In a broad sense, a unit including the control circuit unit 200 and the buffer resistor unit 92 may be referred to as a control circuit unit.

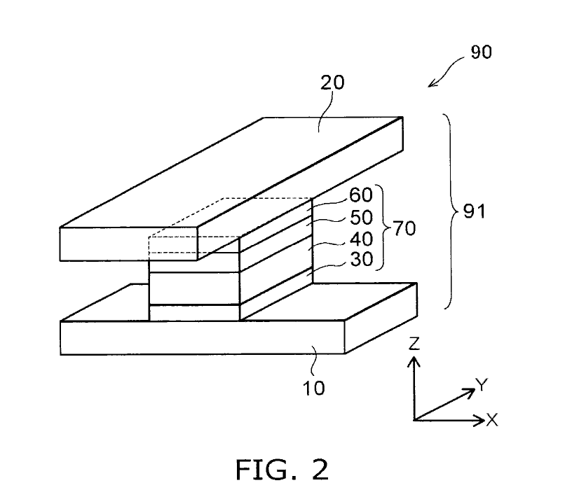

FIG. 2 is a schematic perspective view showing part of the memory cell array unit according to the embodiment.

The bit line 10 (a first interconnection layer) extends in the X-direction (a first direction). The word line 20 (a second interconnection layer) extends in the Y-direction (a second direction) crossing the X-direction. The memory cell 70 (a metal ion source layer 30, a resistance change layer 40, a metal layer 50, and a current limitation layer 60) is provided in a position where the bit line 10 and the word line 20 cross each other. The metal layer 50 may be removed from the memory cell 70 as appropriate.

Memory cells 70 are arranged two-dimensionally in the memory cell mat unit 91, and the memory cell mat unit 91 is stacked in plural; thus, memory cells 70 are arranged three-dimensionally in the X-direction, the Y-direction, and the Z-direction.

The metal ion source layer 30 is provided between the bit line 10 and the word line 20. The metal ion source layer 30 contains at least one element of Au, Ag, Pd, Ir, Pt, W, Hf, Zr, Ti, Ni, Co, Al, Cr, Cu, and the like, for example.

The resistance change layer 40 is provided between the metal ion source layer 30 and the bit line 10. Metal ions released from the metal ion source layer 30 can be diffused into the resistance change layer 40.

The resistance change layer 40 is a layer containing silicon, oxygen, a metal, or others. For example, the resistance change layer 40 contains silicon oxide (SiO), polysilicon, alumina, hafnia, or the like. The resistance change layer 40 may be a stacked body in which one of a silicon oxide film, a polysilicon film, an alumina film, and a hafnia film is combined. The resistance change layer 40 is not limited to a silicon-containing layer. Also GST, HfO,, AIOₓ, etc. may be used. Such a layer is the matrix of the resistance change layer 40.

The resistance of the resistance change layer 40 can be changed by diffusing metal ions released from the metal ion source layer 30 into the matrix or returning the diffused metal ions to the metal ion source layer 30.

The current limitation layer 60 is provided between the bit line 10 and the resistance change layer 40. The current limitation layer 60 may be provided between the word line 20 and the metal ion source layer 30. The metal layer 50 is provided between the resistance change layer 40 and the current limitation layer 60. The current limitation layer 60 is a high resistive layer having a certain level of electrical conductivity. The current limitation layer 60 contains at least one element of Mo, W, Ta, Ti, Si, Ge, C, Ga, As, N, P, and the like, for example.

A prescribed voltage is applied between the word line 20 and the bit line 10, for example. Herein, a high electric potential is applied to the bit line 10 with respect to the word line 20. Thereby, metal ions are released from the metal ion source layer 30 to the resistance change layer 40 side, and the resistance of the memory cell 70 transitions from the high resistance state “0” to the low resistance state “1”. This operation is referred to as a set operation (writing). The voltage when the set operation is performed is referred to as a set voltage, and the current flowing through the memory cell 70 during set voltage application is referred to as a set current. The state of the memory cell 70 after the set operation may be referred to as a set state.

Next, a low electric potential is applied to the bit line 10 with respect to the word line 20. Thereby, metal ions return from the resistance change layer 40 to the metal ion source layer 30 side, and the resistance of the memory cell 70 transitions from the low resistance state “1” to the high resistance state “0”; thus, the date written in the memory cell 70 are erased. This operation is referred to as a reset operation. The state of the memory cell 70 after the reset operation may be referred to as a reset state. Such control of the electric potential of the bit line 10 and the word line 20 is made by the control circuit unit.

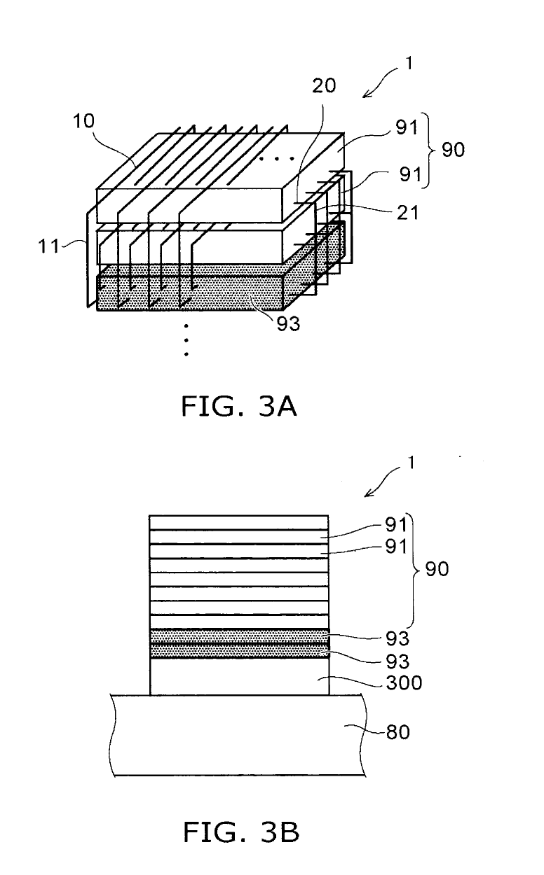

FIG. 3A is a schematic perspective view showing the memory cell array unit and a circuit structure under the memory cell array unit according to the embodiment, and FIG. 3B is a schematic side view showing the memory cell array unit, and a circuit unit and a semiconductor substrate under the memory cell array unit according to the embodiment.

As shown in FIG. 3A, in the nonvolatile memory device 1, the memory cell mat unit 91 including a plurality of bit lines 10, a plurality of word lines 20, and memory cells 70 is stacked in the direction from a semiconductor substrate 80 toward the memory cell array unit 90. The integrated circuit unit (select transistor unit) 93 is provided on the lower side of the memory cell array unit 90.

The nonvolatile memory device 1 includes the semiconductor substrate 80 and includes the memory cell array unit 90 on the upper side of the semiconductor substrate 80 as shown in FIG. 3B. The integrated circuit unit 93 is provided between the memory cell array unit 90 and the semiconductor substrate 80. The peripheral circuit unit 300 is disposed between the integrated circuit unit 93 and the semiconductor substrate 80. The peripheral circuit unit 300 may be provided not only between the integrated circuit unit 93 and the semiconductor substrate 80 but also on the semiconductor substrate 80 other than the region of the semiconductor substrate 80 where the memory cell array unit 90 is disposed.

Each of the plurality of bit lines 10 arranged in each memory cell mat unit 91 is connected to an interconnection 11. The interconnection 11 connected to each of the plurality of bit lines 10 is drawn around to the integrated circuit unit 93.

Here, the interconnections 11 connected to adjacent bit lines 10 are adjacent to each other at a side of the memory cell mat unit 91. In other words, the interconnections 11 connected to adjacent bit lines 10 are juxtaposed to each other at the side of the memory cell mat unit 91. Alternatively, the interconnections 11 connected to adjacent bit lines 10 are disposed on one side and on the other side on the opposite side to this, respectively, of the memory cell mat unit 91. In other words, the interconnections 11 connected to adjacent bit lines 10 are disposed so as to sandwich the memory cell mat unit 91.

Each of the plurality of word lines 20 arranged in each memory cell mat unit 91 is connected to an interconnection 21.

The interconnection 21 connected to each of the plurality of bit lines 10 is drawn around to the integrated circuit unit 93. Each of the plurality of word lines 20 provided in each memory cell mat unit 91 is drawn around to the integrated circuit unit 93 through the interconnection 21, and is connected to a common interconnection. In other words, the plurality of word lines 20 provided in each memory cell mat unit 91 are bundled to one interconnection in a certain place and are at the same electric potential.

Furthermore, the plurality of bit lines 10 provided in each memory cell mat unit 91 may be bundled to one interconnection in a certain place and are at the same electric potential.

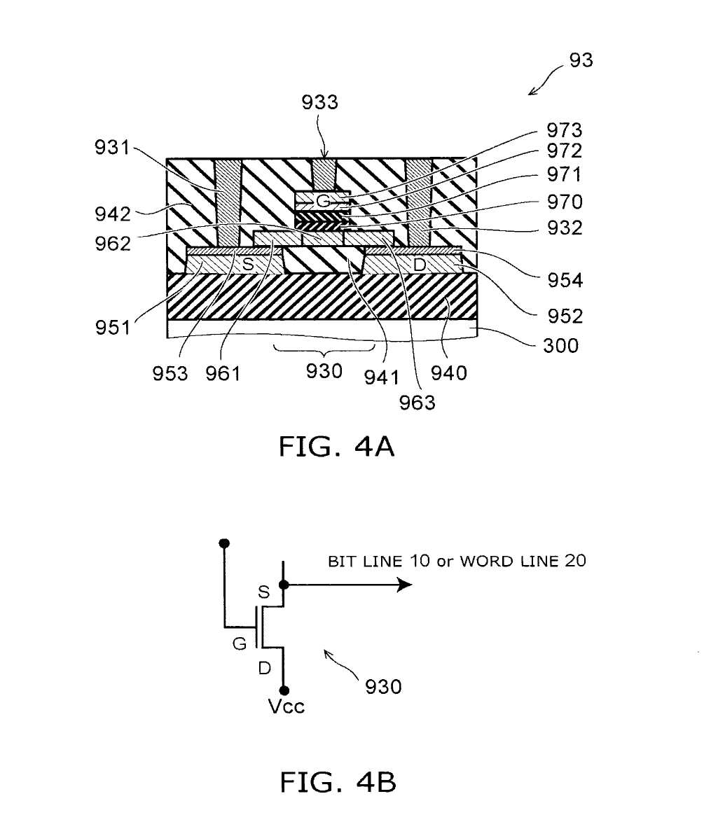

FIG. 4A is a schematic cross-sectional view showing the integrated circuit unit according to the embodiment, and FIG. 4B is a diagram showing an equivalent circuit of the transistor included in the integrated circuit unit according to the embodiment.

In the integrated circuit unit 93 provided on the lower side of the memory cell mat unit 91, a switching element 930 connected to each bit line 10 via each interconnection 11 is disposed. The switching element 930 is connected between a contact electrode 931 and a contact electrode 932. The switching element 930 like this is arranged in plural in the integrated circuit unit 93.

The contact electrode 931 is electrically connected to one of the plurality of bit lines 10. The contact electrode 932 is connected to the peripheral circuit unit 300 (for example, the buffer resistor unit 92) provided on the semiconductor substrate 80. In the switching element 930, the conduction between the contact electrode 931 and the contact electrode 932 is controlled by the control circuit unit provided in the peripheral circuit unit 300.

The switching element 930 is an n-type or an i-type field effect transistor (MOSFET). The integrated circuit unit 93 includes an insulating film 940 provided on the peripheral circuit unit 300, for example. A source electrode 951 and a drain electrode 952 are provided on the insulating film 940. A metal film 953 is provided on the source electrode 951. A metal film 954 is provided on the drain electrode 952. An insulating film 941 is provided between the source electrode 951 and the drain electrode 952.

A salicide film 961, a polysilicon film 962, and a salicide film 963 are provided on the insulating film 941 and on the metal films 953 and 954. The polysilicon film 962 is sandwiched by the salicide film 961 and the salicide film 963. The salicide film 961 is in contact with the metal film 953. The salicide film 963 is in contact with the metal film 954. The polysilicon film 962 is the base region of the MOSFET.

A silicon oxide film 970 is provided on the polysilicon film 962. A hafnia film 971 is provided on the silicon oxide film 970. The silicon oxide film 970 and the hafnia film 971 are the gate insulating film of the MOSFET. A metal film 972 is provided on the hafnia film 971. An electrode layer 973 is provided on the metal film 972. The metal film 972 and the electrode layer 973 are the gate electrode of the MOSFET. A contact electrode 933 is connected to the electrode layer 973. The side surfaces of the contact electrodes 931, 932, and 933 are in contact with an interlayer insulating film 942.

Thus, the switching element 930 has a source (S), a drain (D), and a gate (G). The source (S) of the switching element 930 is connected to the bit line 10 via the contact electrode 931. The drain (D) of the switching element 930 is connected to the peripheral circuit unit 300 (for example, the buffer resistor unit 92) via the contact electrode 932. The drain (D) can be supplied with a prescribed electric potential (Vcc), for example.

The switching element 930 may connect its source (S) side to each bit line 10 and also its source (S) side to the word line 20 via the contact electrode 931 and the interconnection 21. That is, it is possible to connect the contact electrode 931 to a plurality of word lines 20 in common.

The gate (G) of a specific switching element 930 selected by the buffer resistor unit 92 is switched to ON to select one of the plurality of bit lines 10 and increase the electric potential thereof. Thereby, the voltage between the selected bit line 10 and the word line 20 is increased, and the set operation described above is performed.

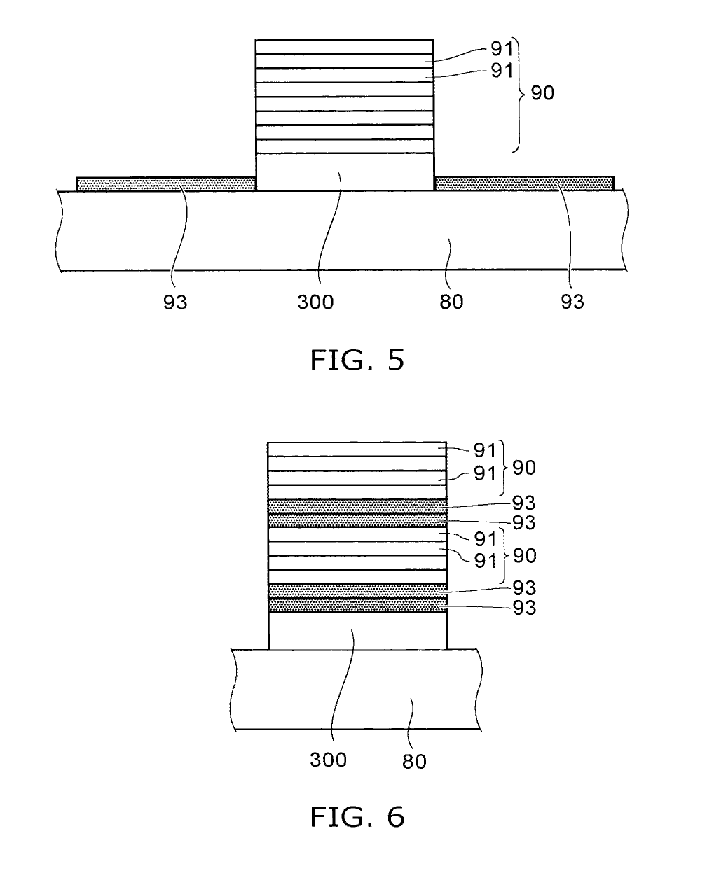

FIG. 5 is a schematic side view showing a memory cell array unit, and a circuit unit and a semiconductor substrate under the memory cell array unit according to a reference example.

In FIG. 5, the integrated circuit unit 93 including select transistors is not provided on the lower side of the memory cell array unit 90 but provided on the semiconductor substrate 80 other than the region where the memory cell array unit 90 is disposed. As described above, one switching element 930 is used for each bit line 10. Therefore, as the number of memory cell mat units 91 stacked increases, the area necessary to place switching elements 930 and contact electrodes 931, 932, and 933 on the semiconductor substrate 80 becomes larger. Therefore, in the reference example, the area of the nonvolatile memory device increases with the increase of the number of memory cell mat units 91 stacked.

In contrast, in the nonvolatile memory device 1 according to the embodiment, the integrated circuit unit 93 including select transistors is disposed on the lower side of the memory cell array unit 90. Therefore, even when the number of memory cell mat units 91 stacked is increased, the region where the integrated circuit unit 93, the contact electrodes 931, 932, and 933, etc. are arranged is within the lower side of the memory cell array unit 90, and the area of the nonvolatile memory device does not increase.

FIG. 6 is a schematic side view showing a memory cell array unit, and a circuit unit and a semiconductor substrate under the memory cell array unit according to a modification example of the embodiment.

The integrated circuit unit 93 is provided between one of the plurality of memory cell mat units 91 and the memory cell mat unit 91 disposed under the one memory cell mat unit. In other words, the integrated circuit unit 93 may be disposed not only on the lower side of the memory cell array unit 90 but also between an upper and a lower memory cell mat unit 91. Also by such a structure, the area increase of the nonvolatile memory device can be suppressed.

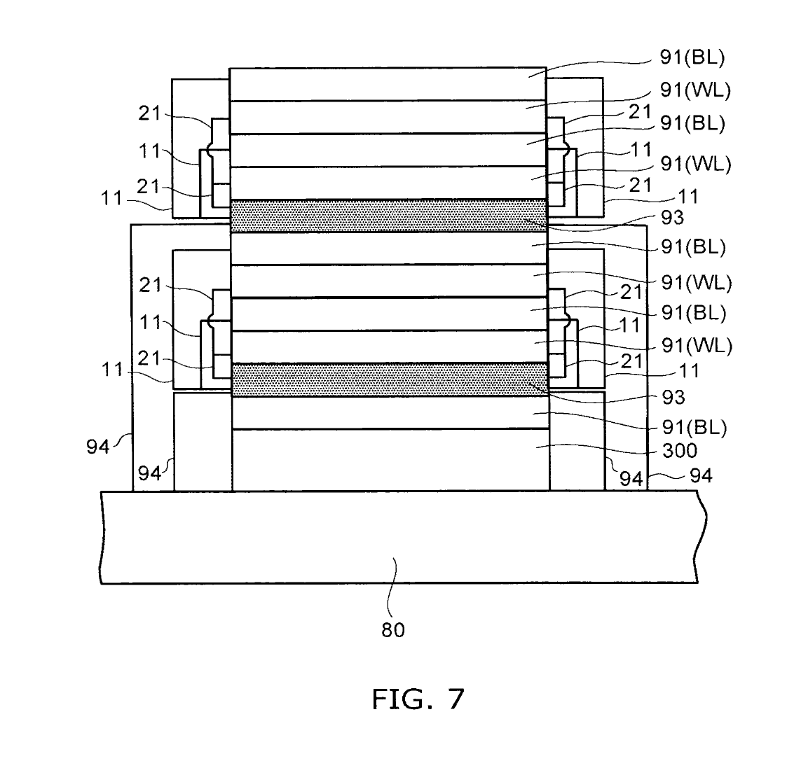

FIG. 7 is a schematic side view showing a memory cell array unit, and a circuit unit and a semiconductor substrate under the memory cell array unit according to another modification example of the embodiment.

As shown in FIG. 7, the peripheral circuit unit 300 is provided on the semiconductor substrate 80. The memory cell mat unit 91 including bit lines 10 is provided on the peripheral circuit unit 300. The lower integrated circuit unit 93 is provided on the memory cell mat unit 91 including bit lines 10. Then, the memory cell mat unit 91 including bit lines 10 and the memory cell mat unit 91 including word lines 20 are arranged alternately one by one in the stacked direction on the lower integrated circuit unit 93.

Furthermore, the upper integrated circuit unit 93 is provided on the memory cell mat unit 91 including bit lines 10. Then, the memory cell mat unit 91 including bit lines 10 and the memory cell mat unit 91 including word lines 20 are arranged alternately one by one in the stacked direction on the upper integrated circuit unit 93.

Each ‘BL’ of the bit lines 10 arranged in each memory cell mat unit 91 is connected to the interconnection 11. The interconnection 11 connected to each of the bit lines 10 is drawn around to the integrated circuit unit 93.

Each ‘WL’ of the word lines 20 arranged in each memory cell mat unit 91 is connected to the interconnection 21. The interconnection 11 connected to each of the word lines 20 is drawn around to the integrated circuit unit 93.

A plurality of interconnections 94 connected to the upper integrated circuit unit 93 are drawn around to the semiconductor substrate 80.

Furthermore, any one of bit lines 10 and any one of the peripheral circuit unit 300 below the lower integrated circuit unit 93 may be used as electric pathways between the lower integrated circuit unit 93 and the semiconductor substrate 80. Furthermore, a plurality of interconnections 94 connected to the lower integrated circuit unit 93 may be drawn around to the semiconductor substrate 80.

Also by such a structure, the area increase of the nonvolatile memory device can be suppressed.

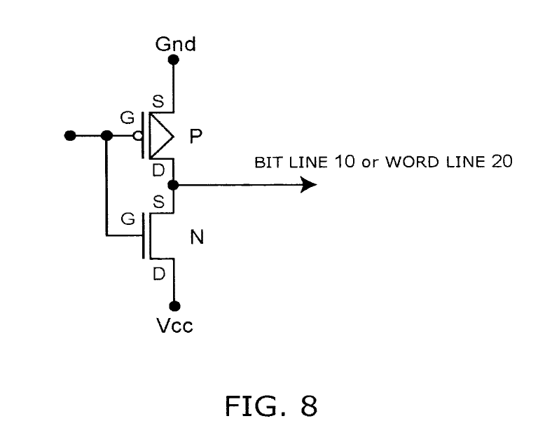

FIG. 8 is an equivalent circuit diagram of select transistors according to the modification example of the embodiment.

In the embodiment, complementary field effect transistors (CMOSFETs) may be used in place of the switching element 930.

The source (S) of a p-type MOSFET is at the ground (Gnd) potential, and the drain (D) of an n-type MOSFET can be supplied with a prescribed electric potential (Vcc), for example. The node between the p-type MOSFET and the n-type MOSFET is connected to the bit line 10 or the word line 20.

By using such a switching element, a prescribed electric potential can be supplied to the bit line 10 or the word line 20 when the electric potential of the gate electrode (G) is the threshold value or more, and the ground potential can be supplied to the bit line 10 or the word line 20 when the electric potential of the gate electrode (G) is smaller than the threshold value.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a semiconductor substrate;
a memory cell array unit provided on an upper side of the semiconductor substrate;
an integrated circuit unit provided between the memory cell array unit and the semiconductor substrate; and
a peripheral circuit unit provided on the semiconductor substrate,
the memory cell array unit including:
a plurality of first interconnection layers extending in a first direction;
a plurality of second interconnection layers extending in a second direction, and the second direction crossing the first direction; and
a memory cell provided in a position, and each of the plurality of first interconnection layers and each of the plurality of second interconnection layers crossing each other in the position,
the integrated circuit unit including:
a first contact electrode electrically connected to one of the plurality of first interconnection layers;
a second contact electrode connected to the peripheral circuit unit; and
a first switching element connected between the first contact electrode and the second contact electrode, and conduction between the first contact electrode and the second contact electrode being controlled by a control circuit unit provided in the peripheral circuit unit.

2. The device according to claim 1, wherein the integrated circuit unit further includes:
a third contact electrode electrically connected to the plurality of second interconnections in common;
a fourth contact electrode connected to the peripheral circuit unit; and
a second switching element connected between the third contact electrode and the fourth contact electrode, and conduction between the third contact electrode and the fourth contact electrode being controlled by a control circuit unit provided in the peripheral circuit unit.

3. The device according to claim 1, wherein a memory mat unit is stacked in a direction from the semiconductor substrate toward the memory cell array unit, and the memory mat unit includes the plurality of first interconnection layers, the plurality of second interconnection layers, and the memory cell.

4. The device according to claim 3, wherein the plurality of second interconnection layers are connected to a common interconnection in the memory mat unit.

5. The device according to claim 3, wherein the integrated circuit unit is further provided between one of the plurality of memory mat units and a memory mat unit disposed under the one memory mat unit.

6. The device according to claim 1, wherein the first switching element includes an n-type or an i-type field effect transistor.

7. The device according to claim 1, wherein the first switching element includes complementary field effect transistors.

8. The device according to claim 1, wherein the first contact electrode is electrically connected to a peripheral circuit provided on the semiconductor substrate.

9. The device according to claim 2, wherein the third contact electrode is electrically connected to a peripheral circuit provided on the semiconductor substrate.

10. The device according to claim 3, wherein each of the plurality of first interconnection layers arranged in the memory cell mat unit is connected to a first interconnection, and the first interconnections connected to adjacent ones of the first interconnection layers are adjacent to each other at a side of the memory cell mat unit.

11. The device according to claim 3, wherein each of the plurality of first interconnection layers arranged in the memory cell mat unit is connected to a first interconnection, and the first interconnections connected to adjacent ones of the first interconnection layers are respectively disposed on one side and on an opposite side to the one side of the memory cell mat unit.

12. The device according to claim 1, wherein the memory cell includes:
a metal ion source layer; and
a resistance change layer, and a metal ion released from the metal ion source layer being capable of diffusing into the resistance change layer.

13. The device according to claim 12, further comprising a current limitation layer between the resistance change layer and the first interconnection layer.

14. The device according to claim 1, the peripheral circuit unit is provided between the semiconductor substrate and the integrated circuit unit.
